(19) United States
(12) Patent Application Publication
(10) Pub. No.: US 2025/0210316 A1
(43) Pub. Date: Jun. 26, 2025

(54) SUBSTRATE PROCESSING APPARATUS USING MICROWAVES

(71) Applicant: SEMES CO., LTD., Cheonan-si (KR)

(72) Inventors: Yoon Seok CHOI, Cheonan-si (KR); Han Lim KANG, Cheonan-si (KR); Tae Hun KANG, Cheonan-si (KR)

(73) Assignee: SEMES CO., LTD., Cheonan-si (KR)

(21) Appl. No.: 18/985,844

(22) Filed: Dec. 18, 2024

(30) Foreign Application Priority Data
Dec. 22, 2023 (KR) 10-2023-0189720

(51) Int. Cl. H01J 37/32

(52) U.S. Cl. CPC H01J 37/32522; H01J 37/32146; H01J 37/3244; H01J 2237/3341

(57) ABSTRACT

Disclosed is a substrate processing apparatus including a chamber having defined therein a processing space for processing of a substrate, a substrate support unit disposed in the chamber, a microwave unit configured to supply microwaves to the processing space, and a polarizer mounted on the sidewall of the chamber and configured to reflect a microwave having first polarization and to transmit a microwave having second polarization. Accordingly, it is possible to solve non-uniformity of the temperature in a plane of the substrate due to a standing wave of the microwaves generated in the processing space.

### CROSS-REFERENCE TO THE RELATED APPLICATION

The present application claims priority to and the benefit of Korean Patent Application No. 10-2023-0189720, filed on Dec. 22, 2023, in the Korean Intellectual Property Office, the entire disclosure of which is incorporated herein by reference.

### BACKGROUND

### 1. Field

The present disclosure relates to a substrate processing apparatus configured to perform predetermined processing on a substrate by supplying microwaves to the interior of a chamber in which the substrate is disposed.

### 2. Description of the Related Art

Generally, a process of processing a substrate such as a semiconductor wafer is carried out with the temperature of the substrate adjusted to a predetermined temperature. A heating module is used in order to raise the temperature of the substrate to a predetermined temperature. As examples of the heating module, there are a resistance heater mounted in a substrate support device and a lamp heater configured to radiate light to a substrate.

In addition to the resistance heating method and the lamp heating method, technology for heating a substrate using microwaves has been proposed. Compared to the resistance heating method or the lamp heating method, heat treatment using microwaves has excellent usability due to the ability thereof to relatively rapidly heat and cool a substrate.

However, microwaves introduced into a chamber in which a substrate is disposed are likely to form a standing wave in the chamber, and thus there may be a difference in the intensity of an electromagnetic field depending on positions in a processing space in the chamber. This causes formation of hot spots and cold spots in a plane of the substrate, leading to non-uniformity of the temperature in the plane of the substrate.

In the field of devices for heating a substrate using microwaves, technology for spraying a controlled cooling gas to each area of a substrate in order to improve the temperature uniformity of the substrate is known (Patent Document 1). However, this technology has problems in that the configuration of a device and a control method are complicated and it is difficult to achieve high temperature uniformity of the substrate.

### RELATED ART DOCUMENT

### Patent Document

(Patent Document 1) KR 10-1747498 B1

### SUMMARY

It is an object of the present disclosure to provide a substrate processing apparatus configured to process a substrate using microwaves while improving the uniformity of the temperature in a plane of the substrate.

In accordance with an aspect of the present disclosure, the above and other objects can be accomplished by the provision of a substrate processing apparatus including a chamber having defined therein a processing space for processing of a substrate, a substrate support unit disposed in the chamber, a microwave unit configured to supply microwaves to the processing space, and a polarizer mounted on a sidewall of the chamber, the polarizer being configured to reflect a microwave having first polarization and to transmit a microwave having second polarization.

In one embodiment of the present disclosure, the polarizer may include a transmission layer mounted on the sidewall of the chamber, the transmission layer including a first surface in contact with the sidewall of the chamber and a second surface formed opposite the first surface so as to be exposed to the processing space, and a plurality of grid patterns mounted on the second surface of the transmission layer exposed to the processing space.

The transmission layer may be made of a material allowing the microwaves supplied from the microwave unit to pass therethrough.

The transmission layer may have a thickness (t) determined through the following equation based on the wavelength (λ) of the microwaves supplied from the microwave unit and the refractive index (n) of the transmission layer.

t=λ/4n

In one embodiment of the present disclosure, the plurality of grid patterns may be mounted in a shape of wires extending in a first direction and spaced a predetermined interval from each other, and the predetermined interval may be less than the wavelength of the microwaves supplied from the microwave unit. Here, the first direction may be a vertical direction identical to the height direction of the chamber or a horizontal direction identical to the peripheral direction of the chamber.

In addition, the microwave having the first polarization may have an oscillation direction perpendicular to the first direction, and the microwave having the second polarization may have an oscillation direction parallel to the first direction.

In one embodiment of the present disclosure, among the microwaves supplied to the processing space from the microwave unit, the microwave having the first polarization may be reflected from the polarizer, and the microwave having the second polarization may pass through the polarizer, may be reflected from the sidewall of the chamber, may pass back through the polarizer, and may then be supplied to the processing space. A standing wave may be formed in the processing space through synthesis of the microwave having the first polarization reflected from the polarizer and the microwave having the second polarization reflected from the sidewall of the chamber. In this case, there may be a phase difference between the microwave having the first polarization reflected from the polarizer and the microwave having the second polarization reflected from the sidewall of the chamber, and the phase difference may be ¼ or ¾ of the wavelength (λ) of the microwaves.

In one embodiment of the present disclosure, the polarizer may be mounted on the entirety of the inner peripheral surface of the sidewall of the chamber, or may be mounted in a first area of the inner peripheral surface of the sidewall of the chamber and may not be mounted in a second area of the inner peripheral surface of the sidewall of the chamber. When the polarizer is mounted only in the first area of the inner peripheral surface of the sidewall of the chamber, the size of the first area in which the polarizer is mounted and the size of the second area in which the polarizer is not mounted may be identical to each other.

In accordance with another aspect of the present disclosure, there is provided a substrate processing apparatus including a chamber having defined therein a processing space for processing of a substrate, a substrate support unit disposed in the chamber, a microwave unit configured to supply microwaves to the processing space, a showerhead disposed between the processing space and the microwave unit, a high-frequency power supply connected to the showerhead or the substrate support unit to supply high-frequency power for generation of plasma to the processing space, a polarizer mounted on a sidewall of the chamber, the polarizer being configured to reflect a microwave having first polarization and to transmit a microwave having second polarization, and a controller.

The showerhead may be made of a microwave transmissive material allowing the microwaves supplied from the microwave unit to pass therethrough, and may include an upper electrode, which is a transparent electrode.

The controller may perform control such that a substrate-processing process is performed, the substrate-processing process including a plasma-processing process of plasma-processing the substrate by controlling the high-frequency power supply to generate plasma in the processing space and a heat treatment process of heat-treating the substrate using the microwaves supplied to the processing space by controlling the microwave unit. Here, the substrate-processing process may be an atomic layer etching (ALE) process.

In addition, the controller may control the high-frequency power supply in a pulsed manner in the plasma-processing process.

### BRIEF DESCRIPTION OF THE DRAWINGS

The accompanying drawings, which are incorporated in this specification, illustrate exemplary embodiments and serve to further illustrate the technical ideas of the disclosure in conjunction with the detailed description of exemplary embodiments that follows, and the disclosure is not to be construed as limited to what is shown in such drawings. In the drawings:

FIG. 1 is a cross-sectional view of a substrate processing apparatus according to an embodiment of the present disclosure;

FIG. 2 is a view for explaining the configuration of a polarizer according to an embodiment of the present disclosure, wherein FIG. 2(a) is a plan view of the polarizer when viewed from a processing space, and FIG. 2(b) is a cross-sectional view taken along line A-A in FIG. 1;

FIG. 3 is a conceptual diagram for explaining temperature distribution in a case in which the polarizer is not mounted;

FIG. 4 is a conceptual diagram for explaining the effect of the polarizer according to the embodiment of the present disclosure;

FIGS. 5 and 6 are schematic cross-sectional views of a chamber when viewed from above to explain arrangement examples of a plurality of grid patterns;

FIG. 7 is a plan view of a polarizer according to another embodiment when viewed from the processing space; and

FIG. 8 is a cross-sectional view of a substrate processing apparatus according to another embodiment of the present disclosure.

### DETAILED DESCRIPTION OF EXEMPLARY EMBODIMENTS

Hereinafter, embodiments of the present disclosure will be described in detail with reference to the accompanying drawings so that those skilled in the art can easily carry out the embodiments. The present disclosure may, however, be embodied in many different forms, and should not be construed as being limited to the embodiments set forth herein.

Parts irrelevant to description of the present disclosure will be omitted to clearly describe the present disclosure, and the same or similar constituent elements will be denoted by the same reference numerals throughout the specification.

In addition, constituent elements having the same configurations in several embodiments will be assigned with the same reference numerals and described only in the representative embodiment, and only constituent elements different from those of the representative embodiment will be described in the other embodiments.

Throughout the specification, when a constituent element is referred to as “comprising”, “including”, or “having” another constituent element, the constituent element should not be understood as excluding other elements, so long as there is no special conflicting description, and the constituent element may include at least one other element.

Unless otherwise defined, all terms used herein, which include technical or scientific terms, have the same meanings as those generally appreciated by those skilled in the art. The terms, such as ones defined in common dictionaries, should be interpreted as having the same meanings as terms in the context of pertinent technology, and should not be interpreted as having ideal or excessively formal meanings unless clearly defined in the specification.

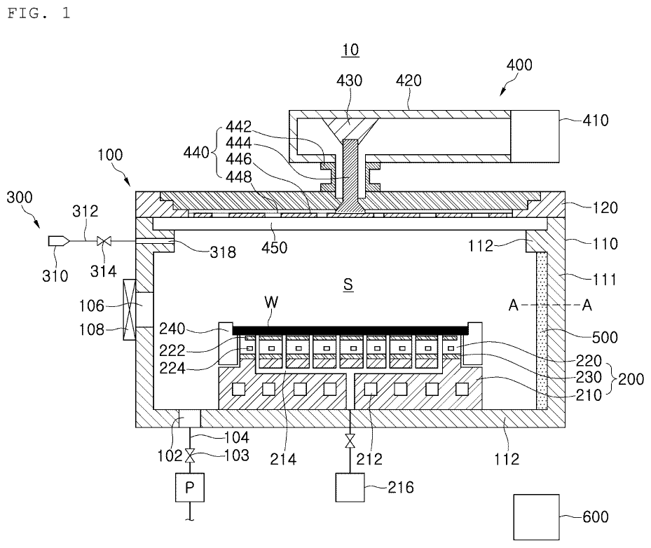

FIG. 1 is a cross-sectional view of a substrate processing apparatus according to an embodiment of the present disclosure.

Referring to FIG. 1, a substrate processing apparatus 10 according to an embodiment of the present disclosure may include a chamber 100, a substrate support unit 200, a gas supply unit 300, a microwave unit 400, a polarizer 500, and a controller 600.

The chamber 100 has defined therein a processing space s in which a substrate-processing process is performed. The chamber 100 may include a chamber body 110 and a chamber cover 120. The chamber body 110 may include a chamber sidewall 111 and a chamber bottom 112, and may be made of metal such as aluminum. The substrate-processing process may be a heat treatment process of heating a substrate W to a predetermined temperature. The substrate-processing process may be performed in a reduced-pressure atmosphere. To this end, the chamber 100 may include an exhaust port 102 formed therein. The exhaust port 102 may be formed in the chamber bottom 112. A vacuum pump P may be connected to the exhaust port 102 via an exhaust line 104 and an exhaust valve 103. The pressure in the processing space s in the chamber 100 may be adjusted to a predetermined pressure by operating the vacuum pump P and controlling the exhaust valve 103. The substrate-processing process may be performed at atmospheric pressure. In this case, the vacuum pump P may be omitted.

An opening 106 may be formed in the sidewall of the chamber 100. The opening 106 functions as a passage through which the substrate W is introduced into and removed from the chamber 100. An opening/closing door 108 is mounted in the opening 106. The opening/closing door 108 functions to open and close the opening 106 in the chamber 100. In the closed state, the opening/closing door 108 hermetically seals the processing space s in the chamber 100. In the open state, the opening/closing door 108 allows the substrate W to be transferred from a transfer space outside the chamber 100 to the processing space s or from the processing space s to the transfer space outside the chamber 100. The opening/closing door 108 may be a gate valve.

A substrate support unit 200 configured to support the substrate W is provided in the chamber 100. The substrate support unit 200 may include an electrostatic chuck 220 configured to attract and fix the substrate W thereto and a base plate 210 configured to support the electrostatic chuck 220. The electrostatic chuck 220 and the base plate 210 may be bonded to each other by means of a bonding layer 230, and the bonding layer 230 may be made of silicone or the like.

The electrostatic chuck 220 may be implemented as a dielectric plate made of alumina or the like, and may be provided therein with a chuck electrode 222 to generate electrostatic force. If voltage is applied to the chuck electrode 222 from a power supply (not shown), electrostatic force is generated, whereby the substrate W is attracted and fixed to the electrostatic chuck 220. Optionally, the electrostatic chuck 220 may be provided with a heater 224 to adjust the temperature of the substrate W.

The base plate 210 may be located under the electrostatic chuck 220, and may be made of metal such as aluminum. The base plate 210 may have formed therein a refrigerant flow path 212 through which a cooling fluid flows, thereby functioning as a cooling device to cool the substrate W. The refrigerant flow path 212 may be provided as a circulation passage through which the cooling fluid circulates.

In addition, the substrate support unit 200 may have a heat transfer gas flow path 214 formed therein to provide a heat transfer gas to a lower surface of the substrate W from a heat transfer gas source 216. The heat transfer gas may facilitate heat transfer between the substrate W and the base plate 210, thereby promoting cooling of the substrate W. Helium (He) may be used as the heat transfer gas.

Optionally, the substrate support unit 200 may include a ring member 240 to surround the periphery of the electrostatic chuck 220. The ring member 240 may have a stepped portion formed on an upper side thereof to support the outer circumferential surface of the substrate W.

If the substrate processing apparatus 10 is an apparatus that performs a heat treatment process on the substrate W, the electrostatic chuck 222 may not be included in the substrate support unit 200. That is, in the present disclosure, the substrate support unit 200 should be broadly understood as a component that is disposed in the processing space s to support the substrate W.

The gas supply unit 300 supplies gas required to process the substrate W to the chamber 100. The gas supply unit 300 may include a gas source 310, a gas supply line 312, and a gas spray nozzle 318. The gas supply line 312 may connect the gas source 310 to the gas spray nozzle 318. A gas supply valve 314 may be mounted on the gas supply line 312 in order to open and close the passage thereof or to regulate the flow rate of fluid flowing through the passage.

Although one gas source 310, one gas supply line 312, and one gas supply valve 314 are illustrated in FIG. 1, the gas source 310 of the present disclosure may include a plurality of gas sources to supply a plurality of gases to the chamber 100 and a plurality of gas supply valves to independently control the supply of the respective gases. The plurality of gases may include a process gas used for a process of processing the substrate W, e.g., a heat treatment gas for creating a heat treatment atmosphere, and may include an inert purge gas.

The microwave unit 400 is disposed above the chamber 100. The microwave unit 400 may include a magnetron 410 configured to generate microwaves, a waveguide 420 configured to transmit the microwaves generated by the magnetron 410, a coaxial converter 430 configured to convert the mode of the microwaves, and an antenna member 440 configured to introduce the microwaves into the processing space s in the chamber 100.

The magnetron 410 may be configured to oscillate microwaves having various frequencies. Among the microwaves generated by the magnetron 410, microwaves having an optimal frequency for processing of the substrate W may be selected.

For example, in order to perform heat treatment on the substrate W, microwaves having a frequency of 2.45 GHz to 5.8 GHz may be provided.

The waveguide 420 may be formed in the shape of a tube having a polygonal or circular cross-section. The inner surface of the waveguide 420 may be made of a conductive material. For example, the inner surface of the waveguide 420 may be made of gold (Au) or silver (Ag). The waveguide 420 provides a passage through which the microwaves generated by the magnetron 410 are transmitted.

The coaxial converter 430 is located in the waveguide 420. The upper end of the coaxial converter 430 is fixed to the inner surface of the waveguide 420. The coaxial converter 430 may be formed in a conical shape in which the cross-sectional area thereof gradually decreases from the upper end thereof to the lower end thereof. The mode of the microwaves transmitted through the inner space in the waveguide 420 is converted by the coaxial converter 430, and the microwaves having the converted mode are propagated downward. For example, the mode of the microwaves may be converted from a transverse electric (TE) mode into a transverse electromagnetic (TEM) mode.

The antenna member 440 transmits the microwaves having a mode converted by the coaxial converter 430 to the processing space s in the chamber 100. The antenna member 440 may include an outer conductor 442, an inner conductor 444, and an antenna 446. The outer conductor 442 is disposed between the waveguide 420 and the chamber cover 120.

The inner conductor 444 is located inside the outer conductor 442. The inner conductor 444 is formed as a pillar-shaped rod, and the outer peripheral surface of the inner conductor 444 is spaced apart from the inner peripheral surface of the outer conductor 442.

The upper end of the inner conductor 444 is connected to the lower end of the coaxial converter 430. The lower end of the inner conductor 444 may penetrate the chamber cover 120 to be connected to the center of the antenna 446. The inner conductor 444 is disposed vertically on the upper surface of the antenna 446.

The antenna 446 is formed in a plate shape. The antenna 446 may be formed as a thin conductive plate. For example, the antenna 446 may be a metal plate having a thickness of several millimeters (mm). A plurality of slot holes 448 for radiation of microwaves is formed in the antenna 446. The arrangement form of the slot holes 448 is not particularly limited. For example, the slot holes 448 may be arranged in a concentric circle shape, a spiral shape, or a radial shape, or may be evenly distributed over the entire surface of the antenna 446. The antenna 446 may be an antenna having a radial line slot array (RLSA) structure.

A transmission window 450 is disposed under the antenna 446. That is, the antenna 446 may be disposed between the chamber cover 120 and the transmission window 450 to be supported by the transmission window 450. The transmission window 450 may be made of a material that allows microwaves to pass therethrough. The transmission window 450 may be made of, for example, quartz. The transmission window 450 may be disposed between the processing space s in the chamber 100 and the antenna 446 while being supported by a support protrusion 112 protruding toward the processing space s from the chamber sidewall 111.

The polarizer 500 is mounted on the inner wall of the chamber 100. The polarizer 500 is mounted on at least a portion of the inner wall of the chamber 100. The polarizer 500 may be mounted on the chamber sidewall 111 and may be mounted in an area below the transmission window 450. As shown in FIG. 1, the polarizer 500 may be mounted only in an area below the support protrusion 112. However, the disclosure is not limited thereto.

The controller 600 may control overall operation of the substrate processing apparatus 10. For example, the controller 600 may control operation of the gas supply unit 300 and the microwave unit 400.

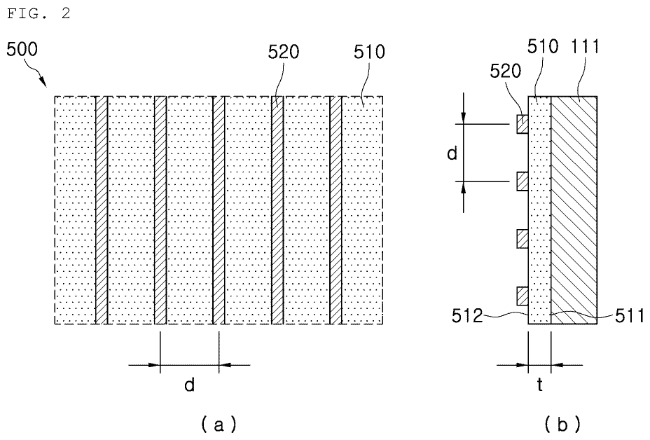

FIG. 2 is a view for explaining the configuration of the polarizer 500 according to an embodiment of the present disclosure. FIG. 2(a) is a plan view of the polarizer 500 when viewed from the processing space s in the chamber 100, and FIG. 2(b) is a cross-sectional view taken along line A-A in FIG. 1 when viewed from above. The chamber body 110 may have a cylindrical shape having a circular cross-section when viewed from above. However, the curvature of the chamber sidewall 111 is not shown in FIG. 2 for convenience of description.

Referring to FIG. 2, the polarizer 500 according to an embodiment of the present disclosure includes a transmission layer 510 and a plurality of grid patterns 520. The transmission layer 510 is made of a material that allows microwaves to pass therethrough. For example, the transmission layer 510 may be made of quartz.

The transmission layer 510 may be mounted on the chamber sidewall 111. For example, the transmission layer 510 may be mounted such that a first surface 511 thereof is in contact with the chamber sidewall 111 and a second surface 512 thereof is exposed to the processing space s in the chamber 100. The thickness t of the transmission layer 510 may be determined within an appropriate range depending on the wavelength λ of the microwaves used for substrate processing and the refractive index n of the transmission layer 510. For example, the thickness t of the transmission layer 510 may be determined to be the thickness obtained using Equation 1 below.

$$t = λ / 4 n \qquad [ Equation 1 ]$$

The plurality of grid patterns 520 may be arranged so as to be spaced a predetermined interval d from each other on the second surface 512 of the transmission layer 510, which faces the processing space s. The grid patterns 520 are made of a material that reflects microwaves. For example, the grid patterns 520 may be made of metal such as aluminum (Al). The grid patterns 520 may be made of the same material as the chamber body 110. The grid patterns 520 may be formed in the shape of a wire extending in a vertical direction (the height direction of the chamber 100) on the second surface 512 of the transmission layer 510.

The interval d between the plurality of grid patterns 520 is set to be less than the wavelength λ of the microwaves supplied from the microwave unit 400. Because the interval d between the grid patterns 520 is set to be less than the wavelength λ of the microwaves, a microwave having first polarization, the oscillation direction of which is perpendicular to the extension direction of the grid patterns 520, among the microwaves supplied to the processing space s may be reflected from the grid patterns 520.

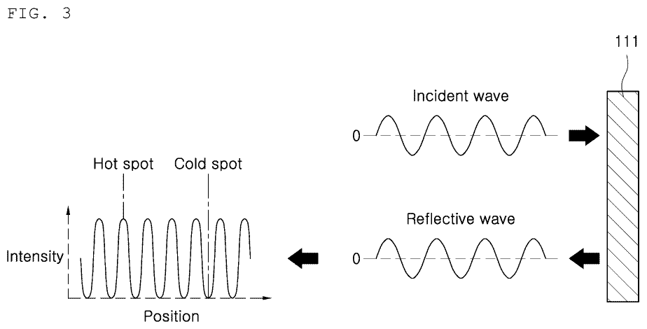

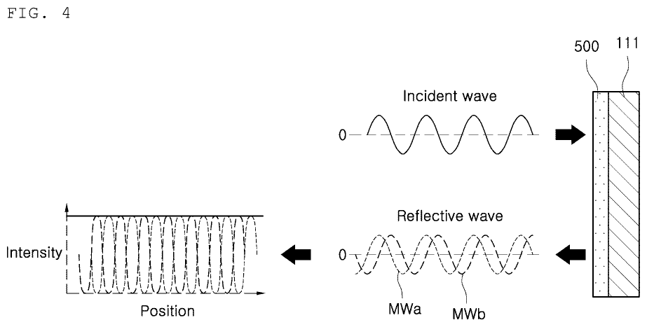

FIGS. 3 and 4 are conceptual diagrams for explaining the effect of the polarizer 500 according to an embodiment of the present disclosure. FIG. 3 shows a case in which the polarizer 500 is not mounted, and FIG. 4 shows a case in which the polarizer 500 is mounted. The polarizer 500 in FIG. 4 is the polarizer 500 shown in FIG. 2, which includes the transmission layer 510 and the plurality of grid patterns 520.

First, referring to FIG. 3, the microwaves incident on the chamber sidewall 111 are reflected from the chamber sidewall 111 regardless of polarization. That is, both a microwave having first polarization and a microwave having second polarization, the oscillation directions of which are perpendicular to each other, are reflected from the chamber sidewall 111, and there is no phase difference between the microwave having the first polarization and the microwave having the second polarization. Therefore, when a standing wave is formed in the processing space s, a difference occurs in the intensity of the electromagnetic field depending on positions. Accordingly, hot spots, at which the intensity of the electromagnetic field is the maximum, and cold spots, at which the intensity of the electromagnetic field is the minimum, are formed in a plane of the substrate W that is processed by the microwaves in the processing space s, resulting in non-uniformity of the temperature in the plane of the substrate W.

In contrast, as shown in FIG. 4, when the polarizer 500 is mounted on the chamber sidewall 111, the microwave MWa having the first polarization among the incident microwaves is reflected from the surface of the polarizer 500, and the microwave MWb having the second polarization among the incident microwaves passes through the polarizer 500 and is reflected from the chamber sidewall 111. Accordingly, a standing wave is formed in the processing space s in the chamber through synthesis of the microwave MWa having the first polarization and the microwave MWb having the second polarization. In this case, the microwave MWb having the second polarization travels further a distance substantially equivalent to the thickness of the transmission layer 510 than the microwave MWa having the first polarization and is then reflected. Thus, a path difference corresponding to approximately twice the thickness of the transmission layer 510 occurs between the microwave MWa having the first polarization and the microwave MWb having the second polarization. Due to this path difference, a phase difference occurs between the microwave MWa having the first polarization and the microwave MWb having the second polarization. Due to this phase difference, the difference in the intensity of the electromagnetic field depending on positions in the processing space s is reduced compared to the configuration shown in FIG. 3.

Because the phase difference between the microwave MWa having the first polarization and the microwave MWb having the second polarization depends on the thickness of the transmission layer 510 of the polarizer 500, it is possible to appropriately form the intensity of the electromagnetic field depending on positions in the processing space s by appropriately adjusting the thickness of the transmission layer 510. In the embodiment of the present disclosure, the phase difference between the microwave MWa having the first polarization and the microwave MWb having the second polarization may be adjusted to ¼ or ¾ of the wavelength λ of the microwaves.

For example, the thickness of the transmission layer 510 of the polarizer 500 may be appropriately selected so that the phase difference between the microwave MWa having the first polarization and the microwave MWb having the second polarization is approximately ¼ of the wavelength λ of the microwaves. In this case, it is possible to make the intensity of the electromagnetic field uniform regardless of positions in the processing space s, thereby greatly improving the uniformity of the temperature in the plane of the substrate W.

The microwave MWa having the first polarization reflected from the surface of the polarizer 500 may be a microwave polarized to oscillate in a direction perpendicular to the extension direction of the grid patterns 520. For example, when the grid patterns 520 are formed to extend in the vertical direction (the height direction of the chamber 100), the oscillation direction of the microwave MWa having the first polarization may be a horizontal direction. That is, the oscillation direction of the microwave MWa having the first polarization may be perpendicular to the extension direction of the grid patterns 520. The microwave MWa having the first polarization may be an S wave.

In order to allow the microwave MWa having the first polarization to be reflected from the surface of the polarizer 500, the interval d between the plurality of grid patterns 520 may be set to be less than the wavelength λ of the microwaves.

The microwave MWb having the second polarization passing through the transmission layer 510 of the polarizer 500 may be a microwave polarized to oscillate in a direction parallel to the extension direction of the grid patterns 520. For example, when the grid patterns 520 are formed to extend in the vertical direction (the height direction of the chamber 100), the oscillation direction of the microwave MWb having the second polarization may be the vertical direction, which is identical to the extension direction of the grid patterns 520. The microwave MWb having the second polarization may be a P wave.

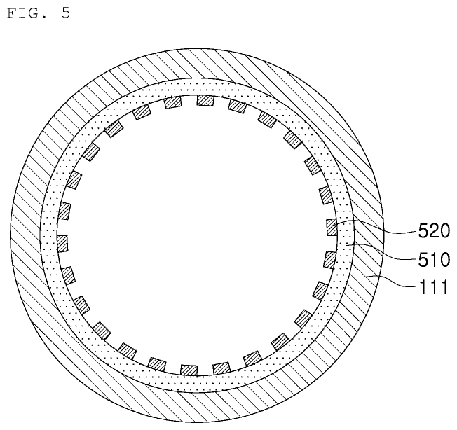

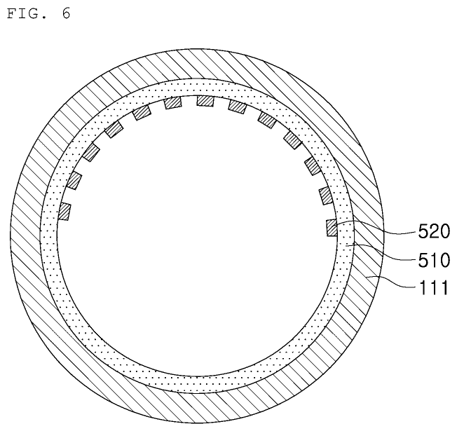

FIGS. 5 and 6 are schematic cross-sectional views of the chamber when viewed from above, in which the plurality of grid patterns 520 is disposed in different forms. As shown in FIG. 5, the plurality of grid patterns 520 may be disposed over the entire area of the inner peripheral surface of the chamber sidewall 111, or as shown in FIG. 6, the plurality of grid patterns 520 may be disposed only on a portion of the inner peripheral surface of the chamber sidewall 111. That is, the plurality of grid patterns 520 may be formed only in a first area of the chamber sidewall 111, and may not be formed in a second area of the chamber sidewall 111. The first area and the second area may have the same size.

Although the transmission layer 510 is illustrated in FIG. 6 as being formed in the second area, in which the plurality of grid patterns 520 is not formed, as well as the first area, the transmission layer 510 may not be formed in the second area.

Depending on the size of the area in which the grid patterns 520 are formed, the thickness of the transmission layer 510 may be adjusted differently so that an appropriate phase difference occurs between the microwave MWa having the first polarization and the microwave MWb having the second polarization. That is, the thickness of the transmission layer 510 may be adjusted differently between the arrangement structure of the grid patterns 520 shown in FIG. 5 and the arrangement structure of the grid patterns 520 shown in FIG. 6.

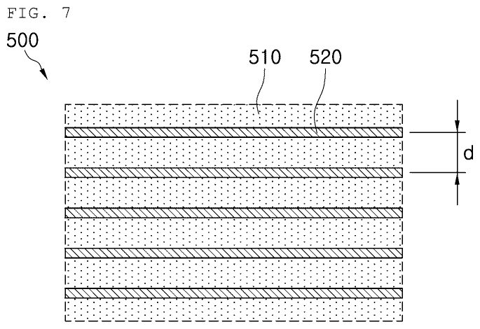

Although the grid patterns 520 have been described with reference to FIG. 2 as being formed on the second surface 512 of the transmission layer 510 so as to extend in the vertical direction (the height direction of the chamber 100), the disclosure is not limited thereto. For example, as shown in FIG. 7, the grid patterns 520 may be formed to extend in the horizontal direction (the peripheral direction of the chamber 100).

Also in this case, the microwave polarized to oscillate in a direction perpendicular to the extension direction of the grid patterns 520 is reflected from the polarizer 500, and the microwave polarized to oscillate in a direction parallel to the extension direction of the grid patterns 520 passes through the transmission layer 510 of the polarizer 500 and is then reflected from the chamber sidewall 111. However, unlike the embodiment shown in FIG. 2, the microwave polarized to oscillate in the vertical direction (the height direction of the chamber 100) may be reflected from the polarizer 500, and the microwave polarized to oscillate in the horizontal direction (the peripheral direction of the chamber 100) may pass through the transmission layer 510 and may then be reflected from the chamber sidewall 111.

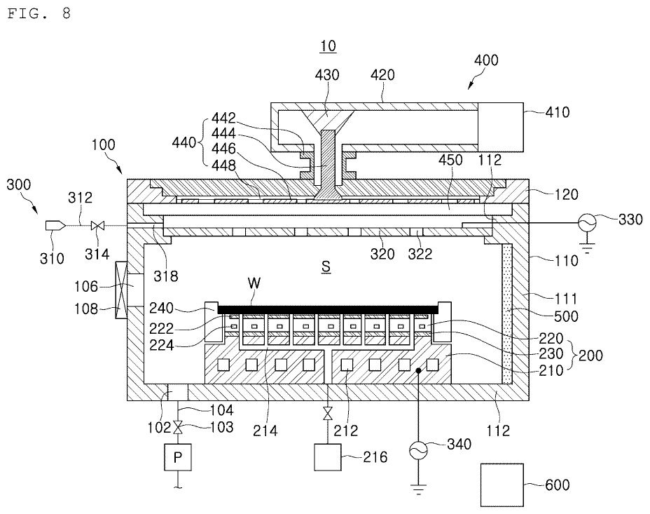

FIG. 8 is a view showing a substrate processing apparatus according to another embodiment of the present disclosure. The embodiment shown in FIG. 8 is identical to the embodiment shown in FIG. 1 except that a showerhead 320 and high-frequency power supplies 330 and 340 for generation of plasma are additionally included. The same components as those of the embodiment shown in FIG. 1 are denoted by the same reference numerals, and duplicate descriptions thereof will be omitted.

Referring to FIG. 8, the substrate processing apparatus 10 according to another embodiment of the present disclosure further includes a showerhead 320 to spray gas to the processing space s. The showerhead 320 may be mounted so as to face the substrate support unit 200 in the vertical direction in the chamber 100. The gas supplied through the gas spray nozzle 318 is sprayed to the processing space s through a plurality of gas spray holes 322 formed in the showerhead 320. The showerhead 320 may be formed to have a larger diameter than the substrate W to be processed and the electrostatic chuck 220.

The showerhead 320 may be made of a microwave transmissive material to allow the microwaves supplied from the microwave unit 400 to pass therethrough and to be transmitted to the substrate W.

The showerhead 320 may function as an upper electrode for generation of plasma. To this end, the showerhead 320 may include an electrode connected to an upper power supply 330 or the ground. The upper power supply 330 may be a high-frequency power supply configured to provide high-frequency power in the range of several hundred kHz to several hundred MHz. The electrode may be a transparent electrode coated on the surface of the showerhead 320 or embedded in a body of the showerhead 320. For example, the electrode may be an indium tin oxide (ITO) electrode.

The substrate support unit 200 may function as a lower electrode. To this end, a lower power supply 340 or the ground may be connected to the base plate 210. The lower power supply 340 may be a high-frequency power supply configured to provide high-frequency power in the range of several hundred kHz to several hundred MHz.

In order to generate plasma in the processing space s, the upper electrode may be grounded, and high-frequency power may be applied to the lower electrode from the lower power supply 340. Optionally, high-frequency power may be applied to the upper electrode from the upper power supply 330, and the lower electrode may be grounded. Alternatively, high-frequency power may be applied both to the upper electrode and to the lower electrode. The high-frequency power supplies 330 and 340 may apply power to the upper electrode or the lower electrode in a continuous mode or a pulse mode.

The controller 600 may control overall operation of the substrate processing apparatus 10. For example, the controller 600 may control operation of the gas supply unit 300, the microwave unit 400, and the high-frequency power supplies 330 and 340.

The substrate processing apparatus 10 shown in FIG. 8 may be used to perform plasma processing and/or heat treatment using microwaves on the substrate W. For example, the substrate processing apparatus 10 may be used to perform plasma processing on the substrate W or may be used to perform heat treatment on the substrate W. Alternatively, the substrate processing apparatus 10 may be used to perform a heat treatment process of heat-treating the substrate W using microwaves after a plasma-processing process of plasma-processing the substrate W.

The controller 600 may control the gas supply unit 300 to supply a predetermined precursor gas to the processing space s, and may control the high-frequency power supplies 330 and 340 to generate plasma in the processing space s, thereby performing a plasma-processing process in which a reaction layer that reacts with the precursor is formed on the surface of the substrate W. Subsequently, the controller 600 may control the microwave unit 400 to supply microwaves to the processing space s in order to heat the substrate W, thereby performing a heat treatment process in which the reaction layer generated in the plasma-processing process is removed. The substrate-processing process may be an atomic layer etching (ALE) process.

As is apparent from the above description, according to the present disclosure, a synthetic wave of a microwave having first polarization and a microwave having second polarization, which have a phase difference therebetween, is generated in a chamber by a polarizer mounted on the inner wall of the chamber, thereby improving the uniformity of the temperature in a plane of a substrate.

Although the embodiments of the present disclosure have been disclosed for illustrative purposes, those skilled in the art will appreciate that various modifications, additions and substitutions are possible, without departing from the scope and spirit of the disclosure.

The scope of the present disclosure should be defined only by the appended claims, and all technical ideas within the scope of equivalents to the claims should be construed as falling within the scope of the disclosure.

What is claimed is:

1. A substrate processing apparatus comprising:
a chamber having a processing space for processing of a substrate;
a substrate support unit disposed in the chamber;
a microwave unit configured to supply microwaves to the processing space; and
a polarizer mounted on a sidewall of the chamber, the polarizer being configured to reflect a microwave having first polarization and to transmit a microwave having second polarization.

2. The substrate processing apparatus as claimed in claim 1, wherein the polarizer comprises:
a transmission layer mounted on the sidewall of the chamber, the transmission layer comprising a first surface in contact with the sidewall of the chamber and a second surface formed opposite the first surface so as to be exposed to the processing space; and
a plurality of grid patterns mounted on the second surface of the transmission layer exposed to the processing space.

3. The substrate processing apparatus as claimed in claim 2, wherein the transmission layer is made of a material allowing the microwaves supplied from the microwave unit to pass therethrough.

4. The substrate processing apparatus as claimed in claim 3, wherein the transmission layer has a thickness (t) determined through an equation below:
$$t = λ / 4 n ,$$
where λ represents a wavelength of the microwaves supplied from the microwave unit, and n represents a refractive index of the transmission layer.

5. The substrate processing apparatus as claimed in claim 3, wherein the plurality of grid patterns is mounted in a shape of wires extending in a first direction and spaced a predetermined interval from each other, and
wherein the predetermined interval is less than a wavelength of the microwaves supplied from the microwave unit.

6. The substrate processing apparatus as claimed in claim 5, wherein the first direction is a vertical direction identical to a height direction of the chamber or a horizontal direction identical to a peripheral direction of the chamber.

7. The substrate processing apparatus as claimed in claim 6, wherein the microwave having the first polarization has an oscillation direction perpendicular to the first direction, and
wherein the microwave having the second polarization has an oscillation direction parallel to the first direction.

8. The substrate processing apparatus as claimed in claim 1, wherein, among the microwaves supplied to the processing space from the microwave unit, the microwave having the first polarization is reflected from the polarizer, and the microwave having the second polarization passes through the polarizer, is reflected from the sidewall of the chamber, passes back through the polarizer, and is then supplied to the processing space, and
wherein a standing wave is formed in the processing space through synthesis of the microwave having the first polarization reflected from the polarizer and the microwave having the second polarization reflected from the sidewall of the chamber.

9. The substrate processing apparatus as claimed in claim 8, wherein there is a phase difference between the microwave having the first polarization reflected from the polarizer and the microwave having the second polarization reflected from the sidewall of the chamber.

10. The substrate processing apparatus as claimed in claim 9, wherein the phase difference is ¼ or ¾ of a wavelength (A) of the microwaves.

11. The substrate processing apparatus as claimed in claim 1, wherein the polarizer is mounted on an entirety of an inner peripheral surface of the sidewall of the chamber.

12. The substrate processing apparatus as claimed in claim 1, wherein the polarizer is mounted in a first area of an inner peripheral surface of the sidewall of the chamber, and is not mounted in a second area of the inner peripheral surface of the sidewall of the chamber.

13. The substrate processing apparatus as claimed in claim 12, wherein the first area and the second area have the same size.

14. A substrate processing apparatus comprising:
a chamber having a processing space for processing of a substrate;
a substrate support unit disposed in the chamber;
a microwave unit configured to supply microwaves to the processing space;
a showerhead disposed between the processing space and the microwave unit;
a high-frequency power supply connected to the showerhead or the substrate support unit to supply high-frequency power to the processing space for generation of plasma; and
a polarizer mounted on a sidewall of the chamber, the polarizer being configured to reflect a microwave having first polarization and to transmit a microwave having second polarization.

15. The substrate processing apparatus as claimed in claim 14, wherein the showerhead is made of a microwave transmissive material allowing the microwaves supplied from the microwave unit to pass therethrough.

16. The substrate processing apparatus as claimed in claim 15, wherein the showerhead comprises an upper electrode, and
wherein the upper electrode is a transparent electrode.

17. The substrate processing apparatus as claimed in claim 14, further comprising:
a controller configured to:
control the high-frequency power supply to generate plasma in the processing space for a substrate-processing process; and
control the microwave unit to supply the microwaves to the processing space for a heat treatment process.

18. The substrate processing apparatus as claimed in claim 17, wherein the substrate-processing process is an atomic layer etching (ALE) process.

19. The substrate processing apparatus as claimed in claim 17, wherein the controller controls the high-frequency power supply in a pulsed manner.

20. A substrate processing apparatus comprising:
a chamber having a processing space for processing of a substrate;
a substrate support unit disposed in the chamber, the substrate support unit having formed therein a refrigerant flow path to allow a cooling fluid to flow therethrough;
a gas supply unit configured to supply a process gas to the processing space;
a microwave unit configured to supply microwaves to the processing space; and
a polarizer mounted on at least a portion of a sidewall of the chamber, the polarizer being configured to reflect a microwave having first polarization and to transmit a microwave having second polarization,
wherein the polarizer comprises:
a transmission layer mounted on the sidewall of the chamber, the transmission layer comprising a first surface in contact with the sidewall of the chamber and a second surface formed opposite the first surface so as to be exposed to the processing space, the transmission layer being configured to transmit the microwaves supplied from the microwave unit; and
a plurality of grid patterns mounted on the second surface of the transmission layer exposed to the processing space, the plurality of grid patterns being formed to extend in a first direction while being spaced apart from each other at an interval less than a wavelength of the microwaves supplied from the microwave unit, and
wherein the transmission layer has a thickness (t) determined through an equation below:
$$t = λ / 4 n ,$$
where λ represents the wavelength of the microwaves supplied from the microwave unit, and n represents a refractive index of the transmission layer.
